(19) United States
(12) Patent Application Publication
(10) Pub. No.: US 2026/0337096 A1
(43) Pub. Date: Oct. 29, 2026

(54) SOLID MATTER, OPTICAL MEMBER, METHOD FOR PRODUCING SOLID MATTER, MATERIAL FOR FORMING SURFACES, SURFACE FORMATION METHOD, SPECTACLES, TOUCH PANEL, SMARTPHONE, AND TABLET TERMINAL

(71) Applicant: CANON OPTRON, INC., Ibaraki (JP)

(72) Inventors: Manabu KONAGAI, Ibaraki (JP); Moritada TOMATSU, Ibaraki (JP)

(21) Appl. No.: 19/702,050

(22) Filed: Jun. 9, 2026

Related U.S. Application Data
(63) Continuation of application No. PCT/JP2024/045113, filed on Dec. 20, 2024.

(30) Foreign Application Priority Data
Dec. 22, 2023 (JP) 2023-216881

(51) Int. Cl. C03C 17/42; G02B 1/14

(52) U.S. Cl. CPC C03C 17/42; G02B 1/14; C03C 2217/213; C03C 2217/78

(57) ABSTRACT

A solid matter, comprising: a silicon oxide-containing layer; and a polymer brush on the silicon oxide-containing layer, wherein the polymer brush constitutes at least a portion of a surface of the solid matter, the polymer brush has an alkyl group-containing moiety having 14 to 70 carbon atoms, the alkyl group-containing moiety is bound to the silicon oxide via an oxygen atom, the solid matter comprises a polyolefin, the polyolefin is arranged on a side of the polymer brush when viewed from the silicon oxide-containing layer, the polyolefin has 14 to 70 carbon atoms, and in the solid matter, a value of a mass-based ratio of a content of the polyolefin with respect to a content of the alkyl group-containing moiety is 0.11 to 4.00.

### CROSS REFERENCE TO RELATED APPLICATIONS

This application is a Continuation of PCT International Application No. PCT/JP2024/045113, filed on Dec. 20, 2024, which is claiming priority of Japanese Patent Application No. 2023-216881, filed on Dec. 22, 2023, all of which are hereby expressly incorporated by reference into the present application.

### BACKGROUND

### Field of the Technology

The present disclosure relates to: a solid matter that is excellent in scratch resistance and long-term antifouling performance, and a method of producing the same; an optical member including the solid matter; and spectacles, a touch panel, a smartphone, and a tablet terminal, which include the optical member.

The present disclosure also relates to a surface-forming material and a surface formation method, which form a surface excellent in scratch resistance and long-term antifouling performance.

### Description of the Related Art

Optical members such as optical filters and spectacle lenses, and articles such as touch panels and smartphones include antifouling films formed on the outermost layers for the purposes of inhibiting the adhesion of dirt, such as fingerprints, skin oil, sweat, and cosmetics, and facilitating the removal of such dirt. Such antifouling films are required to be excellent in antifouling performance (water repellency and oil repellency) and scratch resistance, and organic fluorine compounds (PFAS) typified by perfluorooctanoic acid (PFOA) and perfluorooctanesulfonic acid (PFOS) are often used. However, regulations on PFAS as substances of concern for potential impacts on the environment and ecosystems are being considered in various countries, and the use of PFAS in antifouling films may be prohibited in the future; therefore, there is a demand for PFAS-free antifouling films.

As a PFAS-free antifouling film, an antifouling coating agent that contains a quaternary ammonium chloride of an amino-modified silicone compound, and an aliphatic amine alkylene oxide adduct is disclosed (Japanese Patent Laid-Open No. 2012-241187). Japanese Patent Laid-Open No. 2012-241187 discloses that a hard surface obtained using the antifouling coating agent exhibits excellent properties in terms of antifouling performance.

Meanwhile, it is generally known that a molecular assembly (polymer brush) having a toothbrush-like structure in which chain-like polymers are grown from a material surface can provide a surface with excellent durability. The polymer brush can be formed by applying a base layer, which has the function of a polymerization initiator, to the material surface, and then performing a polymerization reaction on the base layer. WO 2019/131872 discloses a substrate for polymer brush formation that includes a polymerization initiation layer, as well as a precursor liquid for the production of the substrate for polymer brush formation.

### SUMMARY

As a result of studies conducted by the present inventors, the silicone-based antifouling film disclosed in Japanese Patent Laid-Open No. 2012-241187 was found to have excellent properties in terms of antifouling performance. However, this antifouling film has problems in that it has poor scratch resistance and scratches are thus formed by repeatedly wiping off dirt, and that the long-term use thereof leads to deterioration of the antifouling performance.

Further, in WO 2019/131872, a substrate for polymer brush formation that includes a polymerization initiation layer, and a precursor liquid for the production of the substrate for polymer brush formation are disclosed. However, in WO 2019/131872, it is difficult to, for example, control the molecular weight of the resulting polymer brush due to the use of polymerization reaction; therefore, the present inventors came to consider the problem of difficulty in controlling the structure of the polymer brush. In addition, WO 2019/131872 does not mention the scratch resistance and the long-term antifouling performance of the resulting polymer brush.

The means for solution described in Japanese Patent Laid-Open No. 2012-241187 and WO 2019/131872 are not regarded as sufficient in terms of satisfying both scratch resistance and long-term antifouling performance in an antifouling film and, therefore, a surface excellent in both scratch resistance and long-term antifouling performance is desired.

The present disclosure provides a solid matter that is excellent in both scratch resistance and long-term antifouling performance, and a method of producing the same, as well as an optical member, spectacles, a touch panel, a smartphone, and a tablet terminal.

The present disclosure also provides a surface-forming material and a surface formation method, which form a surface excellent in scratch resistance and long-term antifouling performance.

The solid matter of the present disclosure is a solid matter comprising: a silicon oxide-containing layer; and a polymer brush on the silicon oxide-containing layer,
wherein
the polymer brush constitutes at least a portion of a surface of the solid matter,
the polymer brush has an alkyl group-containing moiety having 14 to 70 carbon atoms,
the alkyl group-containing moiety is bound to the silicon oxide via an oxygen atom,
the solid matter comprises a polyolefin,
the polyolefin is arranged on the side of the polymer brush when viewed from the silicon oxide-containing layer,
the polyolefin has 14 to 70 carbon atoms, and
in the solid matter, the value of a mass-based ratio of a content of the polyolefin with respect to a content of the alkyl group-containing moiety is 0.11 to 4.00.

The optical member of the present disclosure is an optical member comprising the above-described solid matter.

Further, the spectacles of the present disclosure are spectacles comprising the above-described optical member.

Still further, the touch panel of the present disclosure is a touch panel comprising the above-described optical member.

Yet still further, the smartphone of the present disclosure is a smartphone comprising the above-described optical member.

Yet still further, the tablet terminal of the present disclosure is a tablet terminal comprising the above-described optical member.

A method of producing the solid matter of the present disclosure is a solid matter production method comprising, in a following order:
a first vapor deposition step of vacuum-depositing a first vapor deposition material containing a silicon oxide to form the above-described silicon oxide-containing layer; and
a second vapor deposition step of vacuum-depositing a second vapor deposition material to form the polymer brush, which second vapor deposition material comprises:
a first compound having an alkyl group-containing moiety having 14 to 70 carbon atoms, and a hydroxy group; and
a second compound being a polyolefin having 14 to 70 carbon atoms.

The surface-forming material of the present disclosure is a surface-forming material comprising: a first compound having an alkyl group-containing moiety having 14 to 70 carbon atoms, and a hydroxy group; and a second compound being a polyolefin having 14 to 70 carbon atoms.

Moreover, the surface formation method of the present disclosure is a surface formation method using vacuum deposition, the method comprising, in a following order:
a first vapor deposition step of vacuum-depositing a first vapor deposition material containing a silicon oxide to form a silicon oxide-containing layer; and
a second vapor deposition step of vacuum-depositing a second vapor deposition material comprising:
a first compound having an alkyl group-containing moiety having 14 to 70 carbon atoms, and a hydroxy group; and
a second compound being a polyolefin having 14 to 70 carbon atoms.

According to the present disclosure, a solid matter having a surface excellent in both scratch resistance and long-term antifouling performance, and a method of producing the same, as well as an optical member, spectacles, a touch panel, a smartphone, and a tablet terminal can be provided. Further, the present disclosure can provide a surface-forming material and a surface formation method, which form a surface excellent in both scratch resistance and long-term antifouling performance. Features of the present disclosure will become apparent from the following description of embodiments with reference to the attached drawings. The following description of embodiments is described by way of example.

### BRIEF DESCRIPTION OF THE DRAWINGS

FIG. 1 is a schematic view illustrating a configuration of the solid matter of the present disclosure.

FIGS. 2A to 2C provide schematic views illustrating configurations of the solid matter of the present disclosure.

### DESCRIPTION OF THE EMBODIMENTS

Hereinafter, embodiments of the solid matter and the production method thereof, the optical member, the spectacles, the smartphone, and the tablet terminal, as well as the surface-forming material and the surface formation method according to the present disclosure are described referring to preferred embodiments. The present disclosure is, however, not limited to the below-described embodiments.

In the present disclosure, unless otherwise specified, the descriptions indicating numerical ranges, such as “XX or more but YY or less” and “XX to YY”, each mean a numerical range that includes its lower limit and upper limit as end points. Further, when numerical ranges are described in a stepwise manner, an upper limit and an lower limit of the numerical ranges can be combined as desired.

The term “polymer brush” used herein refers to a structure in which chain-like polymers are immobilized on a substrate surface, for example, a molecular assembly having a structure in which chain-like polymers are arranged like a brush on a substrate surface.

In the method of producing a substrate for polymer brush formation disclosed in WO 2019/131872, a polymer brush is formed by applying monomers to a substrate or immersing a substrate in monomers, and then performing a polymerization reaction. In the formation of a polymer brush by such a polymerization reaction, it is difficult to, for example, control the molecular weight of the polymer brush; therefore, control of the structure of the polymer brush is believed to be difficult. Accordingly, it is speculated that the antifouling film disclosed in WO 2019/131872 does not necessarily have sufficient scratch resistance and long-term antifouling performance.

According to the present disclosure, the polymer brush has an alkyl group-containing moiety having specific number of carbon atoms, and the solid matter includes a polyolefin having specific number of carbon atoms at a specific ratio with respect to the content of the alkyl group-containing moiety on the side of the polymer brush when viewed from the silicon oxide-containing layer; therefore, it is thought that a high-density and uniform brush-like molecular assembly is thereby formed, and the solid matter has a surface excellent in scratch resistance and long-term antifouling performance. This is believed to be because the polymer brush has an alkyl group-containing moiety having 14 to 70 carbon atoms, the polyolefin has 14 to 70 carbon atoms, and the polymer brush has a structure similar to that of the polyolefin. When the polymer brush has a structure similar to that of the polyolefin, the affinity between the polymer brush and the polyolefin is high. Therefore, it is believed that the brush-like molecular assembly is likely to be formed more densely and more uniformly, resulting in superior scratch resistance and long-term antifouling performance.

Further, according to the production method of the present disclosure, by forming a polymer brush through vacuum-deposition of a vapor deposition material containing a first compound having an alkyl group-containing moiety having a specific number of carbon atoms and a hydroxy group, and a second compound that is a polyolefin. Accordingly, the molecular length of the resulting polymer brush can be easily to controlled, and, for the above-described reason, a high-density and uniform brush-like molecular assembly is likely to be formed. As a result, it is believed that a solid matter having a surface excellent in scratch resistance and long-term antifouling performance can be produced.

### <Solid Matter>

The solid matter having a surface according to the present disclosure will now be described.

The solid matter includes a silicon oxide-containing layer, a polymer brush on the silicon oxide-containing layer, and a polyolefin. The polymer brush constitutes at least a portion of a surface of the solid matter. Further, the polymer brush has an alkyl group-containing moiety having 14 to 70 carbon atoms. Still further, the alkyl group-containing moiety having 14 to 70 carbon atoms, is bound to silicon oxide via an oxygen atom. Yet still further, the polyolefin is arranged on the side of the polymer brush when viewed from the silicon oxide-containing layer. Yet still further, the polyolefin has 14 to 70 carbon atoms. Moreover, in the solid matter, the value of a mass-based ratio of the content of the polyolefin with respect to the content of the alkyl group-containing moiety is 0.11 to 4.00.

The shape of the polymer brush is not particularly limited and, for example, an aspect in which the polymer brush extends in a direction substantially perpendicular to the silicon oxide-containing layer may be adopted.

The polymer brush includes an alkyl group-containing moiety, which alkyl group has 14 to 70 carbon atoms. The number of carbon atoms of the alkyl group is preferably 16 to 60, more preferably 18 to 60, still more preferably 18 to 40. The alkyl group may be linear or branched; however, it is preferably a linear alkyl group. The alkyl group-containing moiety is preferably a linear aliphatic structure, more preferably a linear alkyl group. When the moiety has such a structure and the solid matter includes the below-described polyolefin, a high-density and uniform brush-like molecular assembly is formed, so that the solid matter is provided with a surface excellent in scratch resistance and long-term antifouling performance.

The alkyl group-containing moiety is a moiety having a structure represented by a general formula: [CₙH₂ₙ₊₁]—. In this formula, n represents the number of carbon atoms of the alkyl group, and n is preferably in a range of 14 to 70, more preferably in a range of 16 to 60, still more preferably in a range of 18 to 60, particularly preferably in a range of 18 to 40.

When the number of carbon atoms of the alkyl group is in this range and the solid matter includes the below-described polyolefin, a high-density and uniform brush-like molecular assembly is formed, so that the solid matter is provided with a surface excellent in scratch resistance and long-term antifouling performance. When the number of carbon atoms of the alkyl group is less than 14, a high-density and uniform brush-like molecular assembly is unlikely to be formed; therefore, the scratch resistance and the antifouling performance are deteriorated. Also, when the number of carbon atoms is more than 70, a high-density and uniform brush-like molecular assembly is unlikely to be formed; therefore, the scratch resistance and the antifouling performance are deteriorated.

The number of carbon atoms of the alkyl group can be adjusted by changing the type of the first compound that contains the alkyl group-containing moiety and a hydroxy group.

The alkyl group-containing moiety may further have an oxyalkylene group such as an oxyethylene group —(CH₂)₂—O— or an oxypropylene group —(CH(CH₃)CH₂)—O—, and preferably has an oxyethylene group.

Such a moiety having an alkyl group and an oxyethylene group is a moiety having a structure represented by a general formula: [C_{n′}H_{2n′+1}]—O—[(CH₂)₂O]ₘ—. In this formula, n′ represents the number of carbon atoms of the alkyl group, and m represents the degree of polymerization of the oxyethylene group. The value of n′+2m, which represents a total number of carbon atoms of the alkyl group and the oxyethylene group in the moiety having the alkyl group and the oxyethylene group, is preferably in a range of 14 to 70, more preferably in a range of 16 to 60, still more preferably in a range of 18 to 60, particularly preferably in a range of 18 to 40. The alkyl group may be linear or branched; however, it is preferably a linear alkyl group. Further, the moiety having the alkyl group and the oxyethylene group is preferably a linear alkyl group having an oxyethylene group.

When the total number of carbon atoms of the alkyl group and the oxyethylene group is in the above-described range, a high-density and uniform brush-like molecular assembly is formed, so that the solid matter is likely to be provided with a surface excellent in scratch resistance and long-term antifouling performance. When the number of carbon atoms is less than 14, a high-density and uniform brush-like molecular assembly is unlikely to be formed, and the scratch resistance and the antifouling performance are thus likely to be deteriorated. Also, when the number of carbon atoms is more than 70, a high-density and uniform brush-like molecular assembly is unlikely to be formed; therefore, the scratch resistance and the antifouling performance are likely to be deteriorated.

The degree of polymerization of the oxyethylene group is not particularly limited, and may be 1 to 20, 1 to 15, or 1 to 10.

The total number of carbon atoms of the alkyl group and the oxyethylene group, and the degree of polymerization of the oxyethylene group can be adjusted by changing the type of the first compound that contains the moiety having the alkyl group and the oxyethylene group, and a hydroxy group.

The arrangement of the polyolefin will now be described with reference to the drawings.

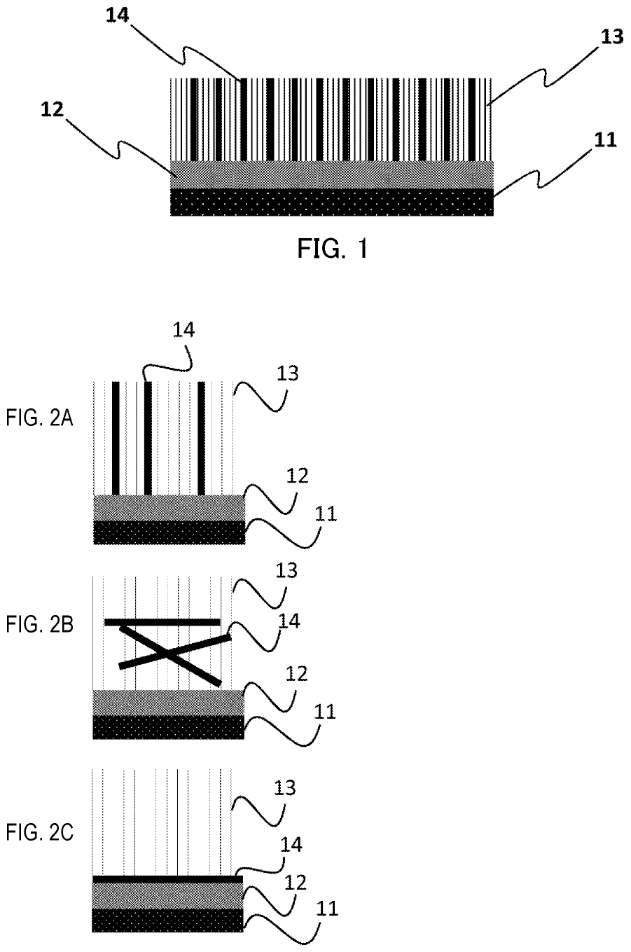

A polyolefin 14 is arranged on the side of a polymer brush 13 when viewed from a silicon oxide-containing layer 12 (FIG. 1). The arrangement of the polyolefin 14 is not particularly limited as long as it is arranged on the side of the polymer brush 13 when viewed from the silicon oxide-containing layer 12, and examples of the arrangement include: an aspect in which the polyolefin 14 is arranged on the silicon oxide-containing layer 12 (FIGS. 2A and 2C); an aspect in which the polyolefin 14 extends in a direction substantially perpendicular to the extending direction of the polymer brush 13; and an aspect in which the polyolefin 14 extends in a direction substantially parallel to the silicon oxide-containing layer 12 (FIG. 2B). More specific examples include: an aspect in which the polyolefin 14 on the silicon oxide-containing layer 12 covers the silicon oxide-containing layer 12 (FIG. 2C); and an aspect in which the polyolefin 14 on the silicon oxide-containing layer 12 extends in a direction substantially parallel to the extending direction of the polymer brush 13 (FIG. 2A).

The polyolefin has 14 to 70 carbon atoms. The number of carbon atoms of the polyolefin is preferably 16 to 60, more preferably 18 to 60, still more preferably 18 to 40. The polyolefin may be linear or branched; however, it is preferably a linear polyolefin. Examples of the polyolefin include a polyethylene and a polypropylene, and the polyolefin is preferably a polyethylene. When the polyolefin is arranged on the side of the polymer brush as viewed from the silicon oxide-containing layer and has such a structure, a high-density and uniform brush-like molecular assembly is formed because of the above-described reasons, so that the solid matter is provided with a surface excellent in scratch resistance and long-term antifouling performance.

When the number of carbon atoms of the polyolefin is less than 14, a high-density and uniform brush-like molecular assembly is unlikely to be formed; therefore, the scratch resistance and the antifouling performance are deteriorated. Also, when the number of carbon atoms of the polyolefin is more than 70, a high-density and uniform brush-like molecular assembly is unlikely to be formed; therefore, the scratch resistance and the antifouling performance are deteriorated.

The polyolefin is preferably a compound having a structure represented by a general formula: —[CₘH₂ₘ]—, more preferably a compound having a methyl group at a terminal. In this formula, m is preferably in a range of 12 to 68, more preferably in a range of 14 to 58, still more preferably in a range of 16 to 58, particularly preferably in a range of 16 to 38.

In the solid matter of the present disclosure, the value of a mass-based ratio of the content of the polyolefin with respect to the content of the alkyl group-containing moiety is 0.11 to 4.00. This value is preferably 0.25 to 4.00, more preferably 0.25 to 1.50. In this range, superior scratch resistance can be obtained.

The value of the mass-based ratio of the content of the polyolefin with respect to the content of the alkyl group-containing moiety is measured by the following method.

A substrate coated with the solid matter is dissolved using an aqueous sodium hydroxide solution (1 mol/L, 100 g) which is an alkaline aqueous solution and, subsequently, a component corresponding to the alkyl group-containing moiety and the polyolefin are extracted with tetrahydrofuran. The component corresponding to the alkyl group-containing moiety is an alcohol (component A described below). Then, from the resulting extract, the component corresponding to the alkyl group-containing moiety and the polyolefin are separated by high-performance liquid chromatography under the following conditions and each quantified. When the mass of the thus quantified component corresponding to the alkyl group-containing moiety and the mass of the thus quantified polyolefin are defined as M1 and M2, respectively, M2/M1 represents the mass-based ratio of the content of the polyolefin with respect to the content of the alkyl group-containing moiety in the solid matter.

The M2/M1 can be adjusted by the value of the mass-based ratio of the content of the second compound, which is the polyolefin, with respect to the content of the first compound, which contains the alkyl group-containing moiety and a hydroxy group, in a surface-forming material.

### (Conditions for High-Performance Liquid Chromatography)

One example of the quantification by high-performance liquid chromatography will now be described.

As a preparative column, an InertSustain C18 preparative column manufactured by GL Sciences Inc. is attached to a preparative high-performance liquid chromatography apparatus, and tetrahydrofuran is used as a developing solvent. The injection amount, the flow rate, and the number of recycles until separation are adjusted for each target to be separated.

In the silicon oxide-containing layer, “silicon oxide” refers to, for example, a compound represented by SiOₓ (wherein, x is, for example, 1 to 2), or SiO₂ in a composite inorganic oxide such as SiO₂·Al₂O₃. The silicon oxide-containing layer is bound to the alkyl group-containing moiety, which constitutes the polymer brush, via an oxygen atom. In other words, the alkyl group-containing moiety is bound to the silicon oxide via the oxygen atom. By this, the durability of the polymer brush can be improved, and the scratch resistance of the solid matter can be enhanced. It is noted here that the mode of the bond is a covalent bond. Further, the aspect of bonding via the oxygen atom may be an aspect in which the alkyl group-containing moiety, which constitutes the polymer brush, and the silicon oxide-containing layer are directly bound to each other, or may be an aspect in which the moiety and the layer are indirectly bound via other linking group.

With the silicon oxide-containing layer, an active site can be formed on the silicon oxide contained in the layer. As a result, the alkyl group-containing moiety in the polymer brush is likely to be bound to the silicon oxide via an oxygen atom. In other words, the polymer brush is likely to be formed on a surface of the solid matter. Examples of a method of forming such an active site include a method of forming a silicon oxide-containing layer by the below-described first vapor deposition step, and a method of modifying a surface by irradiation of a substrate with ultraviolet rays, plasma, or an ion beam.

Examples of a compound that may be contained in the silicon oxide-containing layer include silicon dioxide (SiO₂) and alumina-added silicon dioxide (Al₂O₃-added SiO₂). However, a silicon oxide-containing compound is not limited thereto. The silicon oxide-containing layer may also contain an inorganic oxide, such as indium tin oxide (ITO) or titanium dioxide (TiO₂). The inorganic oxide may be a composite oxide as well.

In the solid matter of the present disclosure, the polymer brush preferably further has a dimethyl silicone chain-containing moiety, which dimethyl silicone chain has 3 to 110 silicon atoms. By incorporating the dimethyl silicone chain-containing moiety, the water repellency and the oil repellency (antifouling performance) can be further improved.

The dimethyl silicone chain-containing moiety is a moiety having a structure represented by a general formula: —[Si(CH₃)₂O]ᵢ—. In this formula, i represents a degree of polymerization of the dimethyl silicone chain, i.e., the number of silicon atoms in the dimethyl silicone chain, and is preferably in a range of 3 to 110, more preferably in a range of 3 to 100, still more preferably in a range of 3 to 50.

The dimethyl silicone chain-containing moiety may further have an alkylene group, such as a methylene group or an ethylene group. The number of carbon atoms of the alkylene group is not particularly limited, and may be, for example, 1 to 6, 1 to 3, or 1 to 2. By allowing the dimethyl silicone chain-containing moiety to further contain an alkylene group, the water repellency and the lipophilicity can be adjusted.

The dimethyl silicone chain-containing moiety has a molecular weight of preferably 200 to 8,000, more preferably 240 to 7,600, still more preferably 300 to 7,600. The molecular weight may be 300 to 8,000 as well.

By controlling the molecular weight to be in the above-described range, the water repellency and the lipophilicity of the dimethyl silicone chain can be further improved.

By changing the type of a third compound that has the dimethyl silicone chain-containing moiety and a reactive functional group, the number of silicon atoms of the dimethyl silicone chain can be adjusted and an alkylene group can be incorporated into the dimethyl silicone chain-containing moiety, so that the molecular weight of the dimethyl silicone chain-containing moiety can be adjusted.

In the solid matter of the present disclosure, a mass-based ratio of the dimethyl silicone chain-containing moiety with respect to the above-described alkyl group-containing moiety and polyolefin in the polymer brush is represented by P_{B}/P_{A}, wherein a sum of the intensity of a peak derived from the alkyl group-containing moiety and the intensity of a peak derived from the polyolefin, which are determined by measuring a surface of the solid matter using a micro-Raman spectrometer, is defined as P_{A}, and the intensity of a peak derived from the dimethyl silicone chain-containing moiety is defined as P_{B}. The P_{B}/P_{A} is preferably 0.0 to 1.1, more preferably 0.1 to 1.0, still more preferably 0.1 to 0.5. In this range, superior scratch resistance can be obtained. The P_{B}/P_{A} may be 0.3 to 0.7 and, in this range, the solid matter can be provided with superior antifouling performance.

The P_{B}/P_{A} can be adjusted by the value of the mass-based ratio of the content of the third compound that has the dimethyl silicone chain-containing moiety and a reactive functional group with respect to a total of the content of the first compound, which has the alkyl group-containing moiety and a hydroxy group, and the content of the second compound that is a polyolefin, in a surface-forming material.

The P_{B}/P_{A} can be determined by the following method.

On a surface of the solid matter, a region to be measured using a micro-Raman spectrometer is determined. This region is determined based on the magnification of the object lens attached to the spectrometer, the excitation laser wavelength, and the aperture diameter. Hereinafter, the determined region is also referred to as “measurement region”.

Next, the measurement region is irradiated with an excitation laser light, and the resulting scattered light is measured to obtain peaks. The measurement conditions are as follows:
Measurement device: micro-Raman spectrometer, manufactured by Thermo Fisher Scientific K.K.
Objective lens magnification×10
Excitation laser wavelength: 532 nm
Aperture diameter: 25 μm
Measurement region: 2 μm

Among the peaks in the thus obtained Raman spectrum, a peak derived from C—C bond is taken as the peak derived from the alkyl group-containing moiety or the peak derived from the polyolefin, and the intensity of this peak is defined as P_{A}. Further, among the peaks in the obtained Raman spectrum, a peak derived from Si—C bond is taken as the peak derived from the dimethyl silicone chain-containing moiety, and the intensity of this peak is defined as P_{B}. The value of P_{B}/P_{A} is calculated from the thus obtained P_{A} and P_{B}.

The solid matter according to the present disclosure may also include any material other than the polymer brush and the polyolefin on the silicon oxide-containing layer, as long as the scratch resistance effect of the present disclosure is not impaired. The total content of the polymer brush and the polyolefin in a total amount of the materials constituting the silicon oxide-containing layer is preferably 80% by mass or more, more preferably 90% by mass or more, still more preferably 95% by mass or more, particularly preferably 100% by mass. An upper limit thereof is not particularly limited, and may be, for example, 80 to 100% by mass, 90 to 100% by mass, or 95 to 100% by mass.

### <Solid Matter Production Method>

Next, the solid matter production method according to the present disclosure will be described.

The solid matter production method includes, in the following order: a first vapor deposition step of vacuum-depositing a first vapor deposition material containing a silicon oxide to form the above-described silicon oxide-containing layer; and a second vapor deposition step of vacuum-depositing a second vapor deposition material to form the polymer brush, which second vapor deposition material contains: a first compound having an alkyl group-containing moiety having 14 to 70 carbon atoms, and a hydroxy group; and a second compound being a polyolefin having 14 to 70 carbon atoms.

In the first vapor deposition step, the first vapor deposition material containing a silicon oxide is vacuum-deposited to form a silicon oxide-containing layer. By performing this first vapor deposition step, a silicon oxide-containing layer can be obtained as a base layer. Further, by forming the silicon oxide-containing layer by the first vapor deposition step, an active site can be formed on the silicon oxide contained in the layer. As a substrate for the vacuum deposition, any known material can be used.

The first vapor deposition material is not particularly limited as long as it contains a silicon oxide, and examples thereof include SiO₂ and Al₂O₃-added SiO₂. The first vapor deposition material may further contain an inorganic oxide, such as Al₂O₃, ITO, or TiO₂. The term “silicon oxide” used herein refers to, for example, a compound represented by SiOₓ (wherein, x is, for example, 1 to 2), or SiO₂ in a composite inorganic oxide such as SiO₂·Al₂O₃.

The conditions for the vacuum deposition in the first vapor deposition step are not particularly limited, and any known conditions can be used.

In the second vapor deposition step, a second vapor deposition material, which contains: a first compound that has an alkyl group-containing moiety, which alkyl group has 14 to 70 carbon atoms, and a hydroxy group; and a second compound that is a polyolefin having 14 to 70 carbon atoms, is vacuum-deposited to form a polymer brush. By performing this second vapor deposition step after the first vapor deposition step, not only the polymer brush can be formed on the silicon oxide-containing layer, but also the alkyl group-containing moiety, which alkyl group has 14 to 70 carbon atoms and which moiety is contained in the polymer brush, can be bound to the silicon oxide contained in the silicon oxide-containing layer via an oxygen atom. This oxygen atom is presumably derived from the hydroxy group contained in the first compound. It is noted here that the mode of the bond is a covalent bond. In addition, by the second vapor deposition step, the polyolefin is arranged on the side of the polymer brush when viewed from the silicon oxide-containing layer. In other words, the solid matter preferably includes a vapor deposition product of the first compound and a vapor deposition product of the second compound.

The first compound, which is contained in the second vapor deposition material, having the alkyl group-containing moiety and a hydroxy group is not particularly limited. Examples thereof include linear aliphatic alcohols and aliphatic alcohols having a branched structure, and the first compound is preferably a linear alkyl alcohol represented by a general formula: [CₙH₂ₙ₊₁]—OH. In this formula, the hydroxy group may be located at the end of the alkyl group or may be located inside; however, it is preferably located at the end. The first compound has the hydroxy group, and can thereby bind to the silicon oxide contained in the silicon oxide-containing layer.

In the formula, n represents the number of carbon atoms in the alkyl group, and is preferably in a range of 14 to 70, more preferably in a range of 16 to 60, still more preferably in a range of 18 to 60, particularly preferably in a range of 18 to 40. Specific examples of the first compound that contains the alkyl group-containing moiety and a hydroxy group include the compounds A-1, A-2, A-3, A-4, and A-6 shown in Table 1.

The polyolefin having 14 to 70 carbon atoms that is contained in the second vapor deposition material is not particularly limited, and examples thereof include linear polyolefins, and polyolefins having a branched structure. Thereamong, the polyolefin is preferably a linear polyethylene. The number of carbon atoms of the polyolefin is preferably 16 to 60, more preferably 18 to 60, still more preferably 18 to 40.

Specific examples of the polyolefin that is the second compound include compounds A′-1, A′-2, and A′-3, and examples of commercially available products include POLYWAX polyethylene manufactured by NuCera Solutions LLC, and Hi-WAX manufactured by Mitsui Chemicals, Inc.

In the solid matter production method, the first compound may be a linear alcohol alkoxylate or an alcohol alkoxylate having a branched structure, and is preferably a linear alcohol ethoxylate represented by a general formula: [C_{n′}H₂ₙ₊₁]—O—[(CH₂)₂O]ₘ—H. The first compound has a hydroxy group at the end of an alkoxylate, and can thereby bind to the silicon oxide contained in the silicon oxide-containing layer.

In this formula, n′ represents the number of carbon atoms in the alkyl group, and m represents the degree of polymerization of the oxyethylene group. The value of n′+2m, which represents a total number of carbon atoms in the linear alcohol ethoxylate is preferably in a range of 14 to 70, more preferably in a range of 16 to 60, still more preferably in a range of 18 to 60, particularly preferably in a range of 18 to 40.

The degree of polymerization of the oxyethylene group is not particularly limited, and may be 1 to 20, 1 to 15, or 1 to 10.

Specific examples of the linear alcohol alkoxylate include compounds A-11, A-12, A-13, and A-14 shown in Table 1.

In the solid matter production method, the first compound may be used singly, or in combination of two or more kinds thereof. In other words, the first compound may be, for example, at least one selected from the group consisting of linear aliphatic alcohols, aliphatic alcohols having a branched structure, linear alcohol alkoxylates, and alcohol alkoxylates having a branched structure. Examples of the linear aliphatic alcohols include 1-tetradecanol, 1-stearyl alcohol, 1-eicosanol, 1-docosanol, 1-triacontanol, 1-hexacontanol, and 1-heptacontanol, and examples of the linear alcohol ethoxylate include ethylene glycol monohexadecyl ether, ethylene glycol monooctadecyl ether, ethylene glycol monooctacosyl ether, and decaethylene glycol tetracontyl ether.

In the solid matter production method, the second compound may be used singly, or in combination of two or more kinds thereof. In other words, the second compound may be, for example, at least one selected from the group consisting of linear polyolefins and polyolefins having a branched structure. Examples of the linear polyolefins include high-density polyethylenes (HDPE), and examples of the polyolefins having a branched structure include low-density polyethylenes (LDPE).

In the second vapor deposition material, the value of a mass-based ratio of the content of the second compound with respect to the content of the first compound is preferably 0.11 to 4.00, more preferably 0.25 to 4.00, still more preferably 0.25 to 1.50.

In the second vapor deposition material, the first compound and the second compound can be used in any combination. Specific examples of the second vapor deposition material include a mixture of A-1 and A′-1, a mixture of A-2 and A′-2, a mixture of A-11 and A′-1, and a mixture of A-12 and A′-2; however, the second vapor deposition material is not limited thereto.

Specific examples of the second vapor deposition material also include commercially available products, such as UNILIN alcohol and UNITHOX ethoxylate, which are manufactured by NuCera Solutions LLC.

In the solid matter production method, the second vapor deposition material may further contain, in addition to the first compound and the second compound, a third compound that has a dimethyl silicone chain-containing moiety and a reactive functional group. The second compound that has a dimethyl silicone chain-containing moiety and a reactive functional group is not particularly limited; however, it is preferably a compound having a structure represented by a general formula: R—[Si(CH₃)₂O]ᵢ—R′.

In this formula, i represents a degree of polymerization of the dimethyl silicone chain, i.e., the number of silicon atoms in the dimethyl silicone chain, and is preferably in a range of 3 to 110, more preferably in a range of 3 to 100, still more preferably in a range of 3 to 50. In the formula, at least one selected from the group consisting of R and R′ is a reactive functional group that can be bound to the silicon oxide-containing layer via an oxygen atom. This oxygen atom is presumably derived from the reactive functional group contained in the third compound. In other words, the reactive functional group is not limited as long as it can be bound to the silicon oxide, and examples of the reactive functional group include alkoxyl groups such as a methoxy group and an ethoxy group, and a hydroxy group. Thereamong, a methoxy group is preferred.

With the at least one selected from the group consisting of R and R′ being a reactive functional group that can be bound to the silicon oxide-containing layer via an oxygen atom, the third compound can be bound to the silicon oxide contained in the silicon oxide-containing layer. It is noted here that the mode of the bond is a covalent bond.

In the group consisting of R and R′, a functional group that is not the reactive functional group is not particularly limited, and examples thereof include alkyl groups such as a methyl group and an ethyl group, and hydrogen. Thereamong, a methyl group is preferred.

The solid matter production method may also include a third vapor deposition step of vapor-depositing the third compound before or after the second vapor deposition step.

The third compound has a molecular weight of preferably 200 to 8,000, more preferably 240 to 7,600, still more preferably 300 to 7,600. The molecular weight may be 300 to 8,000 as well.

Specific examples of the third compound include the compounds B-1, B-2, and B-3 shown in Table 1.

In the second vapor deposition material, the value of a mass-based ratio of the content of the third compound with respect to a total of the content of the first compound and the content of the second compound is preferably 0.0 to 1.1, more preferably 0.1 to 1.0, still more preferably 0.1 to 0.5. The value of the mass-based ratio of the content of the third compound with respect to a total of the content of the first compound and the content of the second compound may be 0.3 to 0.7 and, in this range, P_{B}/P_{A} is likely to be controlled in the above-described range.

As the third compound, a compound that contains a dimethyl silicone chain-containing moiety and a reactive functional group may be used in combination with dimethylpolysiloxane.

### <Surface Formation Method>

Next, the surface formation method according to the present disclosure will be described.

The surface formation method is a surface formation method using vacuum deposition.

The surface formation method includes, in the following order: a first vapor deposition step of vacuum-depositing a first vapor deposition material containing a silicon oxide to form a silicon oxide-containing layer; and a second vapor deposition step of vacuum-depositing a second vapor deposition material comprising: a first compound having an alkyl group-containing moiety having 14 to 70 carbon atoms, and a hydroxy group; and a second compound being a polyolefin having 14 to 70 carbon atoms.

In the first vapor deposition step, the first vapor deposition material containing a silicon oxide is vacuum-deposited to form a silicon oxide-containing layer. By performing this first vapor deposition step, a silicon oxide-containing layer can be formed. Further, by forming the silicon oxide-containing layer by the first vapor deposition step, an active site can be formed on the silicon oxide contained in the layer. As a substrate for the vacuum deposition, any known material can be used.

The first vapor deposition material is not particularly limited as long as it contains a silicon oxide, and examples thereof include SiO₂ and Al₂O₃-added SiO₂. The first vapor deposition material may further contain an inorganic oxide, such as Al₂O₃, ITO, or TiO₂. The term “silicon oxide” used herein refers to, for example, a compound represented by SiOₓ (wherein, x is, for example, 1 to 2), or SiO₂ in a composite inorganic oxide such as SiO₂·Al₂O₃.

The conditions for the vacuum deposition in the first vapor deposition step are not particularly limited, and any known conditions can be used.

In the second vapor deposition step of the surface formation method, a second vapor deposition material, which contains: a first compound that has an alkyl group-containing moiety, which alkyl group has 14 to 70 carbon atoms, and a hydroxy group; and a second compound that is a polyolefin having 14 to 70 carbon atoms, is vacuum-deposited. By performing this second vapor deposition step after the first vapor deposition step, a surface of the resulting solid matter is provided with excellent scratch resistance and long-term antifouling performance. In other words, the solid matter preferably has a surface formed by the surface formation method of the present disclosure.

Examples of the first compound can include the first compound described above in the section of <Solid Matter Production Method>. Examples of the second compound include the second compound described above in the section of <Solid Matter Production Method>.

In the second vapor deposition material, the value of a mass-based ratio of the content of the second compound with respect to the content of the first compound is preferably 0.11 to 4.00, more preferably 0.25 to 4.00, still more preferably 0.11 to 1.50. By controlling this mass-based ratio to be in the above-described range, the resulting solid matter surface is provided with superior scratch resistance.

The second vapor deposition material in the surface formation method may further contain, in addition to the first compound and the second compound, a third compound that has a dimethyl silicone chain-containing moiety and a reactive functional group. As the third compound, the third compound described above in the section of <Solid Matter Production Method> can be used. The surface formation method may also include a third vapor deposition step of vapor-depositing the third compound before or after the second vapor deposition step.

By vapor-depositing the second compound, the resulting solid matter surface is provided with superior water repellency and oil repellency (antifouling performance).

In the second vapor deposition material, the value of a mass-based ratio of the content of the third compound with respect to a total of the content of the first compound and the content of the second compound is preferably 0.0 to 1.1, more preferably 0.1 to 1.0, still more preferably 0.1 to 0.5. By controlling this mass-based ratio to be in the above-described range, the resulting solid matter surface is provided with superior scratch resistance. The value of the mass-based ratio of the content of the third compound with respect to a total of the content of the first compound and the content of the second compound may be 0.3 to 0.7 and, in this range, the resulting solid matter surface is provided with superior antifouling performance.

### <Surface-Forming Material>

Next, the surface-forming material according to the present disclosure will be described.

The surface-forming material contains: a first compound having an alkyl group-containing moiety having 14 to 70 carbon atoms, and a hydroxy group; and a second compound being a polyolefin having 14 to 70 carbon atoms. As the first compound, the first compound described above in the section of <Solid Matter Production Method> can be used. Examples of the second compound include the second compound described above in the section of <Solid Matter Production Method>.

When the surface-forming material contains the first compound and the second compound, a surface obtained by surface-treating a substrate with the surface-forming material is excellent in both scratch resistance and long-term antifouling performance.

The surface-forming material can be used as the second vapor deposition material described above in the section of <Solid Matter Production Method> or <Surface Formation Method>.

In the surface-forming material, the value of a mass-based ratio of the content of the second compound with respect to the content of the first compound is preferably 0.11 to 4.00, more preferably 0.25 to 4.00, still more preferably 0.25 to 1.50. By controlling this mass-based ratio to be in the above-described range, a surface obtained by surface-treating a substrate with the surface-forming material is provided with both excellent scratch resistance and excellent long-term antifouling performance.

The surface-forming material may also contain a third compound that has a dimethyl silicone chain-containing moiety and a reactive functional group. As the third compound, the third compound described above in the section of <Solid Matter Production Method> can be used. By incorporating the third compound into the surface-forming material, a surface obtained by surface-treating a substrate with the surface-forming material is provided with superior water repellency and oil repellency (antifouling performance).

In the surface-forming material, the value of a mass-based ratio of the content of the third compound with respect to a total of the content of the first compound and the content of the second compound is preferably 0.0 to 1.1, more preferably 0.1 to 1.0, still more preferably 0.1 to 0.5. By controlling this mass-based ratio to be in the above-described range, a surface obtained by surface-treating a substrate with the surface-forming material is provided with superior scratch resistance. The mass-based ratio of the content of the third compound with respect to a total of the content of the first compound and the content of the second compound may be 0.3 to 0.7 and, in this range, a surface obtained by surface-treating a substrate with the surface-forming material can be provided with superior antifouling performance.

### <Optical Member>

The optical member is an optical member including the solid matter of the present disclosure.

Examples of the optical member include optical filters, optical lenses, spectacle lenses, photographic lenses, display cover glasses, and various films.

### <Spectacles>

The spectacles are spectacles including the optical member of the present disclosure. The spectacles encompass general instruments worn around the eyes, and are not limited to ordinary spectacles for vision correction, and examples thereof include non-prescription glasses, protective goggles, head-mounted displays, sunglasses, and smart glasses.

### <Touch Panel>

The touch panel is a touch panel including the optical member of the present disclosure. The touch panel of the present disclosure is used in general devices having touch panels. Examples of the devices having touch panels include smartphones and tablet terminals. In other words, the smartphones include the optical member of the present disclosure. Further, the tablet terminals include the optical member of the present disclosure.

TABLE 1

| No. | Structure |
|---|---|
| A-1 | [C₁₈H₃₇]—OH |
| A-2 | [C₂₀H₄₁]—OH |
| A-3 | [C₃₀H₆₁]—OH |
| A-4 | [C₆₀H₁₂₁]—OH |
| A-5 | [C₁₀H₂₁]—OH |
| A-6 | [C₇₀H₁₄₁]—OH |
| A-7 | [C₇₄H₁₄₉]—OH |
| A-11 | [C₁₆H₃₃]—O—[(CH₂)₂O]—H |
| A-12 | [C₁₈H₃₇]—O—[(CH₂)₂O]—H |
| A-13 | [C₂₈H₅₇]—O—[(CH₂)₂O]—H |
| A-14 | [C₄₀H₈₁]—O—[(CH₂)₂O]₁₀—H |
| B-1 | HO—[Si(CH₃)₂O]₃—H |
| B-2 | CH₃—[Si(CH₃)₂O]₂₀—Si[OCH₃]₃ |
| B-3 | CH₃—[Si(CH₃)₂O]₁₀₀—[CH₂]₃—O—[CH₂]₂—OH |

An analysis method of the present disclosure will now be described.

### <Method for Checking Whether Alkyl Group-Containing Moiety is Bound to Silicon Oxide Via Oxygen Atom>

Whether an alkyl group-containing moiety is bound to a silicon oxide via an oxygen atom can be checked by the following procedure.

On each of a substrate A formed of borosilicate glass and a substrate B formed of borosilicate glass, a first vapor deposition material containing a silicon oxide is vacuum-deposited to form a silicon oxide-containing layer. By forming the silicon oxide-containing layer by such a first vapor deposition step, an active site can be formed on the silicon oxide contained in the layer. Subsequently, while maintaining the substrate A in a vacuum state after the formation of the silicon oxide-containing layer, a second vapor deposition material is vacuum-deposited thereon to obtain the solid matter of the present disclosure. The substrate B is taken out of a vacuum deposition apparatus after the formation of the silicon oxide-containing layer, and exposed to atmospheric pressure and air to perform a treatment of eliminating the active site of the silicon oxide contained in the layer, after which the second vapor deposition material is vacuum-deposited.

The substrate A and the substrate B on which the second vapor deposition material has thus been vacuum-deposited are heated in vacuum, and the temperatures at which an alkyl group-containing moiety is detected by a mass spectrometer (trade name: infiTOF-DUO, manufactured by Kanomax Japan Inc.) are compared, whereby whether the alkyl group-containing moiety is bound to the silicon oxide via an oxygen atom can be checked. In the substrate A, since the alkyl group-containing moiety is bound to the silicon oxide via an oxygen atom, the temperature at which the alkyl group-containing moiety is detected is higher than that of the substrate B. The measurement conditions are as follows.
Temperature range: room temperature to 1,000 °C
Heating rate: 10 °C/min
Atmosphere: decompressed state (5×10⁻⁷ Pa or less)
Measurement mass range: m/z 1 to 1,000

The fact that the alkyl group-containing moiety is bound to the silicon oxide via an oxygen atom as determined by the above-described method indicates that the solid matter has a polymer brush on the silicon oxide-containing layer.

### First Embodiment

FIG. 1, which is a schematic view illustrating a configuration of a first embodiment of the solid matter according to the present disclosure, shows a configuration example of the solid matter in which a silicon oxide-containing layer 12 is formed on a substrate 11, a polymer brush 13 is formed on the silicon oxide-containing layer 12, and a polyolefin 14 is arranged on the side of the polymer brush 13 when viewed from the silicon oxide-containing layer 12. It is noted here that FIG. 1 is a schematic representation of a configuration including a polymer brush, and does not represent an accurate ratio of the actual thicknesses of the substrate 11, the silicon oxide-containing layer 12, the polymer brush 13, and the polyolefin 14.

### (Substrate 11)

The substrate 11 may be any solid matter on which the silicon oxide-containing layer 12, the polymer brush 13, and the polyolefin 14 can be formed, and examples of the substrate 11 include glass, ceramics, resins, metals, and films made of glass, resin, or the like. When any of the above-exemplified materials is used as a substrate of an optical member including the solid matter of the present disclosure, the substrate is preferably capable of transmitting visible light or light having a specific wavelength. The thickness of the substrate is not particularly limited, and can be set as appropriate in accordance with the intended use.

### (Silicon Oxide-Containing Layer 12)

The silicon oxide-containing layer 12 is the above-described silicon oxide-containing layer of the present disclosure.

The thickness of the silicon oxide-containing layer 12 is not particularly limited, and may be, for example, 2 nm to 50 nm, or 4 nm to 20 nm.

### (Polymer Brush 13)

The polymer brush 13 is the above-described polymer brush on the silicon oxide-containing layer of the present disclosure.

The thickness of the polymer brush 13 is preferably 1 nm to 50 nm, more preferably 1 nm to 10 nm, still more preferably 1 nm to 5 nm. When this thickness is in the above-described range, a solid matter excellent in scratch resistance and long-term antifouling performance is likely to be obtained.

### (Polyolefin 14)

The polyolefin 14 is arranged on the side of the polymer brush 13 when viewed from the silicon oxide-containing layer of the present disclosure.

The thickness of the polyolefin is preferably 1 nm to 50 nm, more preferably 1 nm to 10 nm, still more preferably 1 nm to 5 nm. When this thickness is in the above-described range, a solid matter excellent in scratch resistance and long-term antifouling performance is likely to be obtained.

### EXAMPLES

The present disclosure will now be described more concretely by way of Examples; however, the present disclosure is not limited to the below-described Examples.

### Example 1

### (Production of Surface-Forming Material)

Table 2 shows: combinations of a component A (first compound) and a component A′ (second compound); mass ratios of the component A′ with respect to the component A; combinations further including a component B (third compound); and mass ratios of the component B with respect to a total mass of the components A and A′. The structures of substances corresponding to the respective symbols in Table 2 are shown in Table 1. In Example 1, a surface-forming material was produced using 20 mg of 1-triacontanol (manufactured by Tokyo Chemical Industry Co., Ltd., product name: 1-Triacontanol), which is A-3 in Table 1, and 5 mg of a polyethylene (A′-2) having a median value of the number of carbon atoms of 30 as the components A and A′, respectively, and this surface-forming material was put into a metal container (Production Example 1). It is noted here that the median value of the number of carbon atoms is a value determined from the weight-average molecular weight of the polymer.

### (Production of Silicon Oxide-Containing Layer)

Using SiO₂ (manufactured by Canon Optron, Inc., product name: SiO2-E-1-2) as a first vapor deposition material, a 10 nm-thick silicon oxide-containing layer 12 made of SiO₂ was formed on a 3 mm-thick borosilicate glass serving as a substrate 11 by a vapor deposition method using a vacuum deposition apparatus (dome diameter: φ900 mm, vapor deposition distance: 890 mm). The thickness of the silicon oxide-containing layer 12 was measured using a spectroscopic ellipsometer (ESM300, manufactured by J.A. Woollam Co., Inc.) and found to be 10 nm.

### (Production of Polymer Brush)

Using the surface-forming material according to Production Example 1 as a second vapor deposition material, a polymer brush 13 and a polyolefin 14 were formed on the silicon oxide-containing layer 12 by a vapor deposition method using a vacuum deposition apparatus (dome diameter: φ900 mm, vapor deposition distance: 890 mm) to obtain an optical member. The thickness of the polymer brush 13 and that of the polyolefin 14 were measured using a spectroscopic ellipsometer (ESM300, manufactured by J.A. Woollam Co., Inc.) and were both found to be 3 nm.

### (Evaluation of Scratch Resistance)

For a surface of the thus produced optical member, the surface scratch resistance was evaluated in accordance with the following method.

First, for the surface of the produced optical member, the water contact angle was measured by the method described below.

Then, steel wool (manufactured by Nihon Steel Wool Co., Ltd., grade: #0000, wire diameter: about 0.012 mm) cut to 1 cm² was reciprocally moved in contact with the surface of the optical member to perform a friction test. In this process, the applied load was adjusted such that a load of 9.8 kgf was applied to the surface, and friction was made under the conditions of a reciprocating speed of 60 reciprocations/min and a moving distance of 15 mm. The number of friction cycles was set at 1,000. Thereafter, the water contact angle was measured.

The water contact angle is an angle formed between a surface of a solid and a tangent to the surface of a water droplet at a point where the solid and the water droplet come into contact. Here, a smaller difference in water contact angle before and after the friction represents fewer scratches on the surface. In other words, a smaller difference in water contact angle before and after the friction represents a higher scratch resistance. When the difference in water contact angle before and after the friction is small and the below-described evaluation of antifouling performance is favorable, it can be judged that the long-term antifouling performance is excellent.

The water contact angle was measured using a contact angle meter (CA-X150, manufactured by Kyowa Interface Science Co., Ltd.). The specific measurement procedure is as follows.

Ion-exchanged water in an amount of 2.5 μL was dropped onto the surface of the optical member. From an image that was obtained 5 seconds after the dropping, the angle formed between the surface of the optical member and a tangent to the surface of the water droplet at a point where the water droplet and the surface of the optical member were in contact was measured. The evaluation results of the scratch resistance are shown in Table 4.

### (Evaluation of Antifouling Performance)

For a surface of the produced optical member, the surface antifouling performance was evaluated in accordance with the following method. The degree of repelling a fluorescent marker ink and the ease of wiping off the ink were used as indices of the antifouling performance and evaluated based on the following criteria. The results thereof are shown in Table 4.

### (Evaluation Criteria)

A: After applying the marker tip to the surface, the ink was repelled in a spherical shape within 5 seconds, and all of the ink could be wiped off with a cotton nonwoven wiper.

B: After applying the marker tip to the surface, the ink was not repelled even after 5 seconds, but all of the ink could be wiped off with CLINT paper.

C: After applying the marker tip to the surface, the ink was not repelled even after 5 seconds, and the ink could not be wiped off even by rubbing with CLINT paper.

### Examples 2 to 27

Surface-forming materials were produced as Production Examples 2 to 27 in the same manner as in Example 1, except that the compounds shown in Table 1 as the components A and B were used in the respective combinations, mass ratios of the component A′ with respect to the component A, and mass ratios of the component B with respect to a total mass of the components A and A′ as shown in Table 2. The following compounds were used as the component A′.
A′-1: A polyethylene in which a lower limit of the number of carbon atoms is 14, an upper limit of the number of carbon atoms is 60, and a median value of the number of carbon atoms is 20
A′-2: A polyethylene in which a lower limit of the number of carbon atoms is 14, an upper limit of the number of carbon atoms is 70, and a median value of the number of carbon atoms is 30
A′-3: A polyethylene in which a lower limit of the number of carbon atoms is 20, an upper limit of the number of carbon atoms is 70, and a median value of the number of carbon atoms is 60
A′-4: A polyethylene in which an upper limit of the number of carbon atoms is 12, and a median value of the number of carbon atoms is 8
A′-5: A polyethylene in which a lower limit of the number of carbon atoms is 80, and a median value of the number of carbon atoms is 100

Optical members were produced using the thus obtained Production Examples 2 to 27. Further, their scratch resistance and antifouling performance were evaluated in the same manner as in Example 1. The results thereof are shown in Table 4.

When the values of the mass-based ratio of the content of the polyolefin with respect to the content of the alkyl group-containing moiety in the thus obtained solid matters were measured by the above-described method using high-performance liquid chromatography, the measured values were found to be consistent with the mass ratios of the component A′ with respect to the component A in the respective surface-forming materials.

Further, when the composition ratios of the component B with respect to a total mass of the components A and A′ in the thus obtained solid matters were measured using a micro-Raman spectrometer, and the measured values were found to be consistent with the mass ratios of the component B with respect to a total mass of the components A and A′ in the respective surface-forming materials.

### Examples 28 to 36

Surface-forming materials were produced as Production Examples 28 to 36 in the same manner as in Example 1, except that the compounds shown in Table 3 as the second vapor deposition material were used in the respective combinations and mass ratios of the component B as shown in Table 3. Optical members were produced using the thus obtained Production Examples 28 to 36. Further, their scratch resistance and antifouling performance were evaluated in the same manner as in Example 1. The results thereof are shown in Table 4.

### Example 37

A surface-forming material was produced using 10 mg of 1-tetradecanol (manufactured by Tokyo Chemical Industry Co., Ltd., product name: 1-Tetradecanol) and 10 mg of 1-docosanol (manufactured by Tokyo Chemical Industry Co., Ltd., product name: 1-Docosanol) as the component A, and 5 mg of a polyethylene (A′-2) having a median value of the number of carbon atoms of 30 as the component A′, and this surface-forming material was put into a metal container to obtain Production Example 37. An optical member was produced using the thus obtained Production Example 37. Further, the scratch resistance and the antifouling performance were evaluated in the same manner as in Example 1. The results thereof are shown in Table 4.

### Example 38

An optical member was obtained in the same manner as in Example 1, except that SiO₂ (manufactured by Canon Optron, Inc., product name: SiO2-E-1-2) and Al₂O₃ (manufactured by Canon Optron, Inc., product name: Al2O3-A-1-2) were used as the first vapor deposition material. The mass ratio of Al₂O₃ was adjusted to be 0.01 with respect to the mass of SiO₂. Further, the scratch resistance and the antifouling performance were evaluated in the same manner as in Example 1. The results thereof are shown in Table 4.

### Comparative Examples 1 to 8

Surface-forming materials were produced as Comparative Production Examples 1 to 8 in the same manner as in Example 1, except that the compounds shown in Table 1 as the components A and B were used in the respective combinations, mass ratios of the component A′ with respect to the component A, and mass ratios of the component B with respect to a total mass of the components A and A′ as shown in Table 2. Optical members were produced using the thus obtained Comparative Production Examples 1 to 8. Further, their scratch resistance and antifouling performance were evaluated in the same manner as in Example 1. The results thereof are shown in Table 4.

### Comparative Example 9

Chloromethylphenylethyltrimethoxysilane (0.564 parts by volume) was added to a mixed solution of a 0.01 M HCl aqueous solution (1 part by volume), tetraethoxysilane (2.8 parts by volume), and ethanol (8 parts by volume), and the resultant was stirred at a room temperature for 24 hours to prepare a precursor liquid.

This precursor liquid was dropped onto a silicon wafer and spin-coated (2,000 rpm/10 seconds), and the silicon wafer was then dried at a room temperature for 24 hours to form a polymerization initiation layer was formed on the surface of the silicon wafer.

A polymerization solution was obtained by mixing 2-(dimethylamino)ethyl methacrylate (5.5 parts by volume), copper (II) chloride (4 parts by volume), N,N,N′,N″,N″-pentamethyl diethylene triamine (7 parts by volume), sodium ascorbate (1 part by volume), and water (1 part by volume). In this polymerization solution, the above-obtained silicon wafer on which the polymerization initiation layer was formed was immersed for 2 hours to form a polymer brush on the surface of the silicon wafer serving as a substrate, whereby an optical member was obtained. Further, the scratch resistance and the antifouling performance were evaluated in the same manner as in Example 1. As a result, the contact angle before friction was found to be 65°, and the contact angle after 1,000 times of friction was found to be 7°. The evaluation result of the antifouling performance was C.

TABLE 2

| | | | | | Component B/ |
|---|---|---|---|---|---|
| | | | Component A′/ | | (Component A + |
| | Component | Component | Component A | Component | Component A′) |
| | A | A′ | (mass ratio) | B | (mass ratio) |
| Production Example 1 | A-3 | A′-2 | 0.25 | — | 0.0 |
| Production Example 2 | A-3 | A′-2 | 0.25 | B-2 | 0.1 |
| Production Example 3 | A-3 | A′-2 | 0.25 | B-2 | 0.5 |
| Production Example 4 | A-3 | A′-2 | 0.25 | B-2 | 1.0 |
| Production Example 5 | A-1 | A′-1 | 0.11 | — | 0.0 |
| Production Example 6 | A-2 | A′-1 | 0.11 | — | 0.0 |
| Production Example 7 | A-4 | A′-1 | 0.11 | — | 0.0 |
| Production Example 8 | A-6 | A′-1 | 0.11 | — | 0.0 |
| Production Example 9 | A-11 | A′-1 | 0.11 | — | 0.0 |
| Production Example 10 | A-14 | A′-1 | 0.11 | — | 0.0 |
| Production Example 11 | A-13 | A′-1 | 0.11 | — | 0.0 |
| Production Example 12 | A-13 | A′-2 | 0.67 | B-2 | 0.1 |
| Production Example 13 | A-13 | A′-2 | 0.67 | B-2 | 0.5 |
| Production Example 14 | A-13 | A′-2 | 0.67 | B-2 | 1.0 |
| Production Example 15 | A-1 | A′-1 | 0.25 | B-2 | 0.5 |
| Production Example 16 | A-2 | A′-2 | 0.25 | B-2 | 0.5 |
| Production Example 17 | A-4 | A′-3 | 0.25 | B-2 | 0.5 |
| Production Example 18 | A-11 | A′-1 | 0.25 | B-2 | 0.5 |
| Production Example 19 | A-12 | A′-2 | 0.25 | B-2 | 0.5 |
| Production Example 20 | A-14 | A′-3 | 0.25 | B-2 | 0.5 |
| Production Example 21 | A-3 | A′-2 | 0.25 | B-1 | 0.5 |
| Production Example 22 | A-3 | A′-2 | 0.25 | B-3 | 0.5 |
| Production Example 23 | A-3 | A′-1 | 0.11 | — | 0.0 |
| Production Example 24 | A-3 | A′-1 | 1.00 | — | 0.0 |
| Production Example 25 | A-3 | A′-1 | 4.00 | — | 0.0 |
| Production Example 26 | A-3 | A′-1 | 0.25 | — | 0.0 |
| Production Example 27 | A-3 | A′-3 | 0.25 | — | 0.0 |
| Production Comparative Example 1 | — | — | — | B-2 | — |
| Production Comparative Example 2 | A-5 | A′-1 | 0.25 | — | 0.0 |
| Production Comparative Example 3 | A-6 | — | — | — | 0.0 |
| Production Comparative Example 4 | A-7 | A′-3 | 0.25 | — | 0.0 |
| Production Comparative Example 5 | A-6 | A′-3 | 0.05 | — | 0.0 |
| Production Comparative Example 6 | A-6 | A′-3 | 9.00 | — | 0.0 |
| Production Comparative Example 7 | A-6 | A′-4 | 0.25 | — | 0.0 |
| Production Comparative Example 8 | A-6 | A′-5 | 0.25 | — | 0.0 |

TABLE 3

| | | | Component B/ |
|---|---|---|---|
| | Second vapor | | Component A |
| | deposition material | Component B | (mass ratio) |
| Production Example 28 | UNILIN425 alcohol | — | 0.0 |
| Production Example 29 | UNILIN425 alcohol | B-2 | 0.5 |
| Production Example 30 | UNILIN425 alcohol | B-2 | 1.0 |
| Production Example 31 | UNILIN350 alcohol | — | 0.0 |
| Production Example 32 | UNILIN550 alcohol | — | 0.0 |
| Production Example 33 | UNILIN700 alcohol | — | 0.0 |
| Production Example 34 | UNIT HOX420 ethoxylate | — | 0.0 |
| Production Example 35 | UNIT HOX420 ethoxylate | B-2 | 0.5 |
| Production Example 36 | UNIT HOX720 ethoxylate | — | 0.0 |

TABLE 4

| | | | Contact | |
|---|---|---|---|---|
| | | Contact | angle | |
| | | angle | after 1,000 | |
| | | before | times of | |
| | | friction | friction | Antifouling |
| | Production No. | [°] | [°] | performance |
| Example 1 | Production Example 1 | 104 | 102 | B |
| Example 2 | Production Example 2 | 107 | 101 | B |
| Example 3 | Production Example 3 | 108 | 101 | A |
| Example 4 | Production Example 4 | 107 | 91 | A |
| Example 5 | Production Example 5 | 105 | 103 | B |
| Example 6 | Production Example 6 | 107 | 104 | B |
| Example 7 | Production Example 7 | 102 | 95 | B |
| Example 8 | Production Example 8 | 103 | 76 | B |
| Example 9 | Production Example 9 | 100 | 98 | B |
| Example 10 | Production Example 10 | 99 | 96 | B |
| Example 11 | Production Example 11 | 100 | 98 | B |
| Example 12 | Production Example 12 | 102 | 99 | B |
| Example 13 | Production Example 13 | 102 | 94 | A |
| Example 14 | Production Example 14 | 107 | 89 | A |
| Example 15 | Production Example 15 | 108 | 100 | A |
| Example 16 | Production Example 16 | 108 | 100 | A |
| Example 17 | Production Example 17 | 105 | 89 | A |
| Example 18 | Production Example 18 | 102 | 93 | A |
| Example 19 | Production Example 19 | 101 | 94 | A |
| Example 20 | Production Example 20 | 99 | 95 | A |
| Example 21 | Production Example 21 | 107 | 101 | A |
| Example 22 | Production Example 22 | 106 | 100 | A |
| Example 23 | Production Example 23 | 104 | 101 | B |
| Example 24 | Production Example 24 | 108 | 102 | B |
| Example 25 | Production Example 25 | 106 | 101 | B |
| Example 26 | Production Example 26 | 104 | 101 | B |
| Example 27 | Production Example 27 | 103 | 101 | B |
| Example 28 | Production Example 28 | 104 | 102 | B |
| Example 29 | Production Example 29 | 106 | 98 | A |
| Example 30 | Production Example 30 | 108 | 94 | A |
| Example 31 | Production Example 31 | 105 | 102 | B |
| Example 32 | Production Example 32 | 104 | 101 | B |
| Example 33 | Production Example 33 | 106 | 102 | B |
| Example 34 | Production Example 34 | 101 | 98 | B |
| Example 35 | Production Example 35 | 105 | 99 | A |
| Example 36 | Production Example 36 | 100 | 97 | B |
| Example 37 | Production Example 37 | 103 | 101 | B |
| Example 38 | Production Example 38 | 105 | 102 | B |
| Comparative Example 1 | Production Comparative Example 1 | 109 | 6 | A |
| Comparative Example 2 | Production Comparative Example 2 | 105 | 56 | C |
| Comparative Example 3 | Production Comparative Example 3 | 101 | 45 | C |
| Comparative Example 4 | Production Comparative Example 4 | 100 | 41 | C |
| Comparative Example 5 | Production Comparative Example 5 | 102 | 55 | C |
| Comparative Example 6 | Production Comparative Example 6 | 108 | 52 | C |
| Comparative Example 7 | Production Comparative Example 7 | 101 | 53 | C |
| Comparative Example 8 | Production Comparative Example 8 | 100 | 42 | C |

For example, a comparison between Example 8 and Comparative Example 3 indicates that the addition of a polyolefin markedly improves the scratch resistance.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

What is claimed is:

1. A solid matter, comprising:
a silicon oxide-containing layer; and
a polymer brush on the silicon oxide-containing layer,
wherein
the polymer brush constitutes at least a portion of a surface of the solid matter,
the polymer brush has an alkyl group-containing moiety having 14 to 70 carbon atoms,
the alkyl group-containing moiety is bound to the silicon oxide via an oxygen atom,
the solid matter comprises a polyolefin,
the polyolefin is arranged on a side of the polymer brush when viewed from the silicon oxide-containing layer,
the polyolefin has 14 to 70 carbon atoms, and
in the solid matter, a value of a mass-based ratio of a content of the polyolefin with respect to a content of the alkyl group-containing moiety is 0.11 to 4.00.

2. The solid matter according to claim 1, wherein the alkyl group-containing moiety further has an oxyethylene group —(CH₂)₂—O—.

3. The solid matter according to claim 1, wherein the alkyl group-containing moiety is a linear aliphatic structure.

4. The solid matter according to claim 1, wherein the alkyl group-containing moiety is a linear alkyl group having an oxyethylene group —(CH₂)₂—O—.

5. The solid matter according to claim 1, wherein the polyolefin is a linear polyolefin.

6. The solid matter according to claim 1, wherein the polymer brush has a thickness of 1 nm to 50 nm.

7. The solid matter according to claim 1, wherein
the polymer brush further has a dimethyl silicone chain-containing moiety having 3 to 110 silicon atoms, and
the dimethyl silicone chain-containing moiety is bound to the silicon oxide via an oxygen atom.

8. The solid matter according to claim 7, wherein the dimethyl silicone chain-containing moiety has a molecular weight of 200 to 8,000.

9. An optical member, comprising the solid matter according to claim 1.

10. Spectacles, comprising the optical member according to claim 9.

11. A touch panel, comprising the optical member according to claim 9.

12. A smartphone, comprising the optical member according to claim 9.

13. A tablet terminal, comprising the optical member according to claim 9.

14. A surface formation method using vacuum deposition, the method comprising, in a following order:
a first vapor deposition step of vacuum-depositing a first vapor deposition material containing a silicon oxide to form a silicon oxide-containing layer; and
a second vapor deposition step of vacuum-depositing a second vapor deposition material comprising:
a first compound having an alkyl group-containing moiety having 14 to 70 carbon atoms, and a hydroxy group; and
a second compound being a polyolefin having 14 to 70 carbon atoms.

15. The surface formation method according to claim 14, wherein the first compound is a linear aliphatic alcohol.

16. The surface formation method according to claim 14, wherein the first compound is a linear alcohol ethoxylate.

17. The surface formation method according to any one of claim 14, wherein the polyolefin is a linear polyolefin.

18. The surface formation method according to any one of claim 14, wherein, in the second vapor deposition material, a value of a mass-based ratio of a content of the second compound with respect to a content of the first compound is 0.11 to 4.00.

19. The surface formation method according to any one of claim 14, wherein the second vapor deposition material further comprises a third compound having a dimethyl silicone chain-containing moiety and a reactive functional group.

20. The surface formation method according to claim 19, wherein, in the second vapor deposition material, a value of a mass-based ratio of a content of the third compound with respect to a total of a content of the first compound and a content of the second compound is 0.1 to 1.0.
